(19) United States
(12) Patent Application Publication
(10) Pub. No.: US 2018/0188858 A1
(43) Pub. Date: Jul. 5, 2018

(54) DISPLAY PANEL, METHOD OF MANUFACTURING THE SAME, AND DISPLAY DEVICE

(71) Applicants: BOE TECHNOLOGY GROUP CO., LTD., Beijing (CN); Beijing BOE Optoelectronics Technology Co., Ltd., Beijing (CN)

(72) Inventors: Yong Zhang, Beijing (CN); Yue Li, Beijing (CN); Shijun Wang, Beijing (CN); Zhenhua Lv, Beijing (CN); Wenjun Xiao, Beijing (CN)

(21) Appl. No.: 15/736,230

(22) PCT Filed: Apr. 18, 2017
(86) PCT No.: PCT/CN2017/080911

§ 371 Date: Dec. 13, 2017

(30) Foreign Application Priority Data
May 13, 2016 (CN) 201610319651.6

(51) Int. Cl. G06F 3/047; G06F 3/041; G09G 5/04; G09G 3/20; H01L 21/8234

(52) U.S. Cl. CPC G06F 3/047; G06F 3/0412; G09G 5/04; G09G 2320/0666; H01L 21/823475; H01L 21/823437; G06F 2203/0339; G09G 3/2003

(57) ABSTRACT

Disclosed is a display panel, a method of manufacturing the same, and a display device. The display panel includes: a plurality of sub pixels arranged in rows and columns, wherein sub pixels in one of two adjacent rows of sub pixels are offset from sub pixels in the other row, respectively, in a column direction, and each sub pixel has a different color from an adjacent sub pixel; a plurality of data lines extending in the column direction in a column gap between the sub pixels; a plurality of touch signal lines provided in a gap between the sub pixels; and a plurality of touch detection electrodes electrically connected to the plurality of touch signal lines, respectively. The touch detection electrodes are used as a common electrode of the sub pixels, and the touch signal line is provided in a film layer between the common electrode and a pixel electrode of the sub pixel, respectively. A part of the film layer in a thickness direction of the display panel is provided between the touch control signal line and the pixel electrode of the sub pixel.

### CROSS-REFERENCE TO RELATED APPLICATION

This application is a Section 371 National Stage Application of International Application No. PCT/CN2017/080911, filed on Apr. 18, 2017, entitled “DISPLAY PANEL AND MANUFACTURING METHOD THEREFOR, AND DISPLAY DEVICE”, which claims priority to Chinese Application No. CN201610319651.6, filed on May 13, 2016, incorporated herein by reference in their entirety.

### BACKGROUND

### Technical Field

The present disclosure relates to a display technology field, more particularly, relates to a display panel, a method of manufacturing the display panel, and a display device.

### Description of the Related Art

At present, a display panel becomes higher and higher in display accuracy, and a rendering technology is more and more widely used in the display panel. The rendering technology may make the display effect better through a transferring relationship between pixels. Meanwhile, touch technology has been widely introduced into the display panel, in particular, an embedded (or in-cell) touch panel in which touch detection electrodes are embedded in the display panel, which may reduce the overall thickness of modules of the display panel, and significantly decrease the cost of the touch panel.

### SUMMARY

According to an object of the present disclosure, there is provided a display panel, a method of manufacturing the display panel, and a display device.

According to an aspect of an exemplary embodiment of the present disclosure, there is provided a display panel, comprising:

a plurality of sub pixels arranged in rows and columns, wherein sub pixels in one of two adjacent rows of sub pixels are offset from sub pixels in the other row, respectively, in a column direction, and each sub pixel has a different color from an adjacent sub pixel;

a plurality of data lines extending in the column direction in a column gap between the sub pixels;

a plurality of touch signal lines provided in a gap between the sub pixels; and

a plurality of touch detection electrodes electrically connected to the plurality of touch signal lines, respectively,

the touch detection electrodes are used as a common electrode of the sub pixels, and the touch signal line is provided in a film layer between the common electrode and a pixel electrode of the sub pixel, respectively, and

a part of the film layer in a thickness direction of the display panel is provided between the touch control signal line and the pixel electrode of the sub pixel.

According to an exemplary embodiment of the display panel, the data lines are provided in an additional film layer different from the film layer.

According to an exemplary embodiment of the display panel, extending directions of the touch signal lines are consistent with those of the data lines, respectively.

According to an exemplary embodiment of the display panel, wherein an orthographic projection of the data line, which is in the column gap between two columns of sub pixels, on a plane perpendicular to the thickness direction of the display panel covers an orthographic projection of the touch signal line in the same column gap.

According to an exemplary embodiment of the display panel, the touch signal lines are in one-to-one correspondence to the touch detection electrodes. A floating touch signal line is provided in the column gap between two columns of sub pixels except for the column gap in which the touch signal line is provided, and an extending direction of the floating touch signal line is consistent with that of the data line.

According to an exemplary embodiment of the display panel, an orthographic projection of the data line, which is in the column gap between two columns of sub pixels, on a plane perpendicular to the thickness direction of the display panel covers an orthographic projection of the floating touch signal line in the same column gap.

According to an exemplary embodiment of the display panel, in a first row of sub pixels, a second row of sub pixels and a third row of sub pixels which are arranged sequentially, the first row of sub pixels and the third row of sub pixels are aligned to each other in the column direction, respectively.

According to an exemplary embodiment of the display panel, each of the data lines is only connected to pixel switches of the sub pixels located at different sides of the data line and having the same color.

According to an exemplary embodiment of the display panel, each of the data lines is connected to pixel switches of the sub pixels located at the same side of the data line.

According to another aspect of an exemplary embodiment of the present disclosure, there is provided a display device comprising the display panel according to any one of above exemplary embodiments.

According to another aspect of an exemplary embodiment of the present disclosure, there is provided a method of manufacturing the display panel according to any one of above exemplary embodiments, the method comprising a step of:

sequentially forming patterns of a gate electrode, a gate insulation layer, an active layer, source and drain data lines, a resin layer, the common electrode, a first insulation layer, the touch signal lines, a second insulation layer and the pixel electrodes on a substrate; or

sequentially forming patterns of a gate electrode, a gate insulation layer, an active layer, source and drain data lines, a resin layer, the pixel electrodes, the touch signal lines insulated from the pixel electrodes, a first insulation layer and the common electrode on a substrate.

### BRIEF DESCRIPTION OF THE DRAWINGS

The above and other features of the present disclosure will become more apparent by describing in detail exemplary embodiments thereof with reference to the accompanying drawings, in which:

FIG. 1 is an illustrative view of an arrangement of pixels of a display panel according to an exemplary embodiment of the present disclosure;

FIG. 2 is an illustrative local view of a display panel in the relevant art;

FIG. 3 is an illustrative local view of a display panel with double line data structure in the relevant art;

FIG. 4a is an illustrative cross section view of a display panel according to an exemplary embodiment of the present disclosure;

FIG. 4b is an illustrative cross section view of a display panel according to another exemplary embodiment of the present disclosure;

FIG. 5 is an illustrative local view of a display panel according to an exemplary embodiment of the present disclosure; and

FIG. 6 is an illustrative view of an arrangement of pixels of a display panel according to another exemplary embodiment of the present disclosure.

### DETAILED DESCRIPTION OF PREFERRED EMBODIMENTS

Hereafter, it will describe in detail a display panel, a method of manufacturing the display panel and a display device with reference to drawings according to exemplary embodiments of the present disclosure.

Although it will describe the present disclosure with reference to drawings in preferred embodiments, those skilled in this art may modify the present disclosure described herein to obtain the same technical effect. Therefore, the description herein is only a broad disclosure for those skilled in this art, and the scope of the present disclosure is not limited to exemplary embodiments of the present disclosure. The shape and size of each film layer in the drawings do not reflect the true proportion of the display panel, but the purpose is only to explain the contents of the present disclosure.

In an embedded touch panel in the relevant art, in order to meet the touch accuracy, hundreds of touch detection electrodes are usually provided in the display panel. It needs to provide a corresponding signal connection line for example, a touch signal line, for each touch detection electrode. If the touch signal lines are led out from left and right ends of the display panel, it is not conducive to the design of narrow bezel. Thereby, a dual data line scheme is generally used, that is, an additional touch signal line is arranged in a longitudinal direction by a film layer in which the data line is provided. However, the additional touch signal line is apt to affect a display aperture rate, especially in a display panel with high precision. Moreover, the touch precision is far less than the display accuracy. Thereby, the number of the touch signal lines is less than that of the data lines. The luminous environment of the sub pixel provided with the touch signal lines is different from that of the sub pixel without the touch signal lines, and it will have adverse effects on the display effect.

In the display panel using the rendering technology, two adjacent sub pixels in two adjacent rows of sub pixels are not aligned to each other in the column direction and offset from each other by a distance less than a width of one pixel. Therefore, the data line is arranged a fold line. When the dual data line scheme is used to set the touch signal line, a short circuit problem may be easily occurred between the data line and the touch signal line.

According to a general concept of an exemplary embodiment of the present disclosure, there is provided a display panel, comprising:

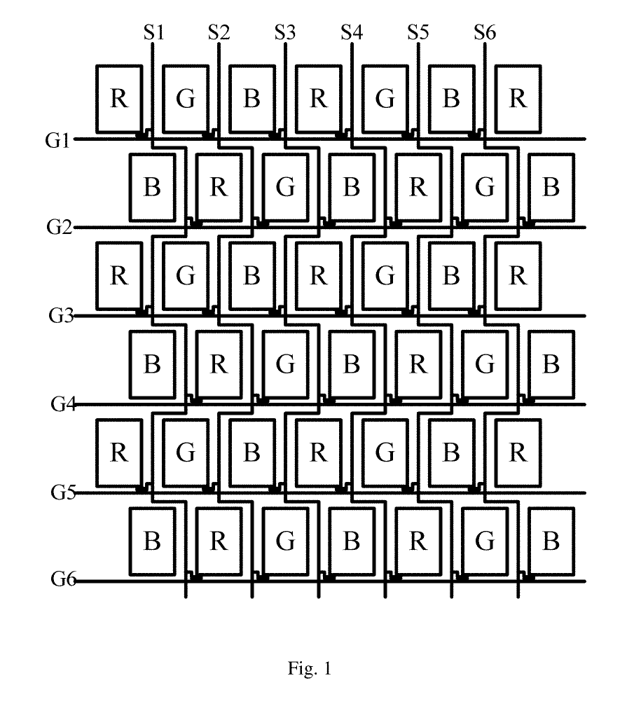

a pixel structure, as shown in FIG. 1, formed by a plurality of sub pixels compactly arranged in rows and columns; sub pixels in one of two adjacent rows of sub pixels are offset from sub pixels in the other row, respectively, in a column direction by X (0<X<1) times of width of the sub pixel, and each sub pixels in each row of sub pixels has a different color from an adjacent sub pixel;

a plurality of data lines S1, S2, . . . , S6 extending in the column direction in a column gap between the sub pixels;

a plurality of touch signal lines provided in a gap between the sub pixels; and

a plurality of touch detection electrodes electrically connected to the plurality of touch signal lines, respectively,

wherein the touch detection electrodes are used as a common electrode of the sub pixels of the pixel structure, respectively, and the touch signal line is provided in a film layer between the common electrode and pixel electrode of the sub pixel of the pixel structure, respectively, and

wherein a part of the film layer in a thickness direction of the display panel is provided between the touch control signal line and the pixel electrode of the sub pixel.

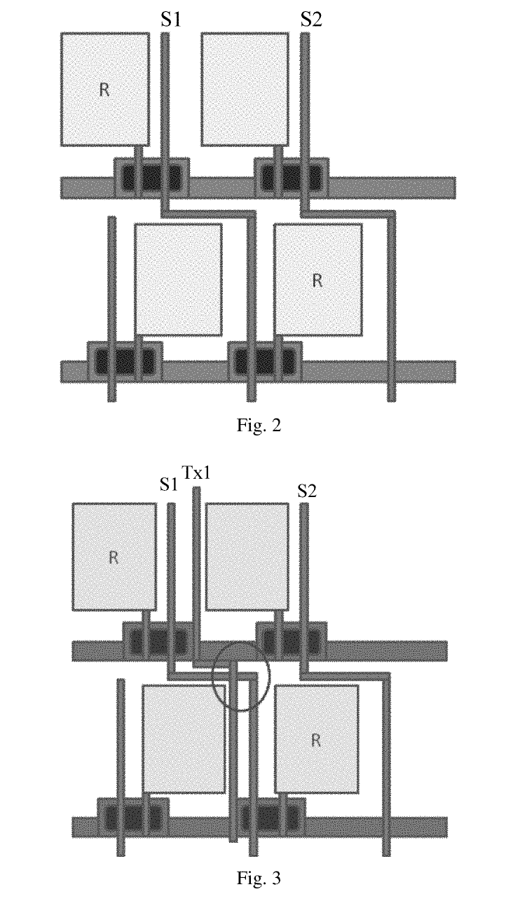

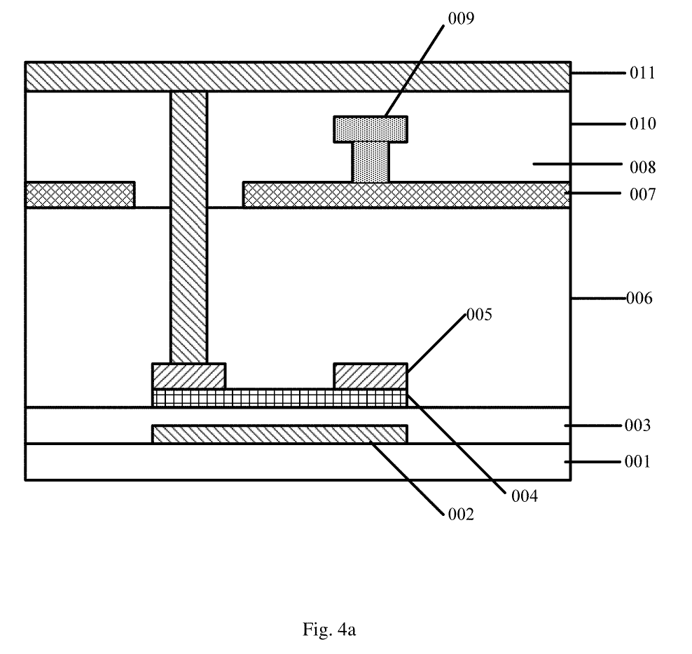

When displaying a solid (single) color picture, in order to reduce the power consumption, the data line may be set to one data line and connected to the sub pixels with one color. In this way, the one data line is connected to the sub pixels in different rows and at left and right sides of the data line, as shown in FIG. 2. At this time, if the dual data line scheme is adopted to set the touch signal line, as shown in FIG. 3, short circuit may be occurred between the data line S1 and the touch signal line Tx1 (as shown in the circle of FIG. 3). Thereby, it is not suitable to provide the touch signal line on the film layer where the data line is provided.

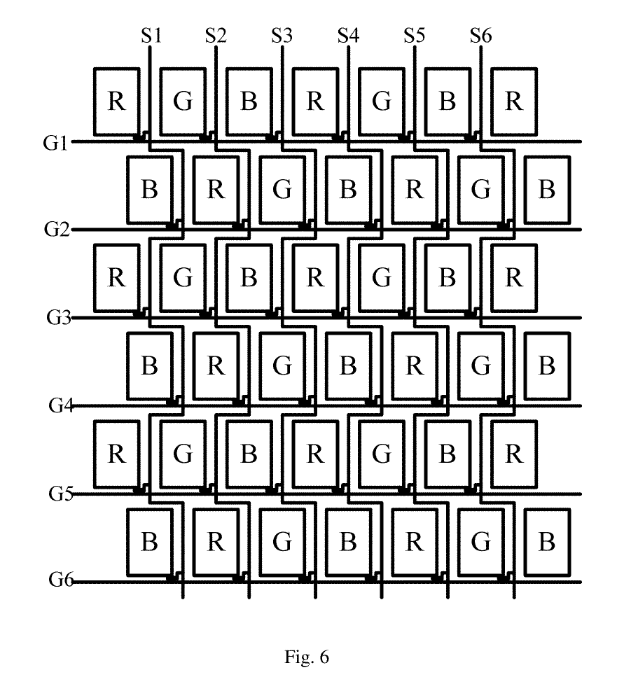

In the above display panel according to an exemplary embodiment of the present disclosure adopting the rendering technology, as shown in FIGS. 1 and 6, any two adjacent sub pixels have different colors, that is, two adjacent sub pixels at least partly aligned in the column direction have different colors, and two adjacent sub pixels in the same row also have different colors. If the display panel is combined with a driving circuit (UC), the display effect of the display panel may be improved by a virtual algorithm. For example, the display effect of one pixel may be achieved by using two adjacent sub pixels (such as B pixel and R pixel) in the same row. However, for the display panel in the relevant art, the display effect of one pixel is achieved by using three adjacent sub pixels (such as B pixel, R pixel, and G pixel) in the same row.

In an embodiment, based on the display panel using the rendering technology, the touch signal line and the data line may be provided in different film layers by use of a gap between the sub pixels. By providing the touch signal line and the data line in different film layers, it will neither affect the aperture ratio of the display panel, nor lead to the luminous environment difference among the sub pixels caused by providing the touch signal lines. Moreover, since the data line and the touch signal line are located in different film layers, it may avoid the short circuit from being occurred between the data line and the touch signal line when the touch signal line and the data line are provided in the same film layer.

In the above display panel according to the exemplary embodiments of the present disclosure, the touch detection electrodes constitute a common electrode of the sub pixels in the pixel structure, respectively, so as to simplify the structure of the display panel. Therefore, the common electrode is also used as the touch detection electrodes, and the touch function is realized without increasing the number of film layers in the display panel.

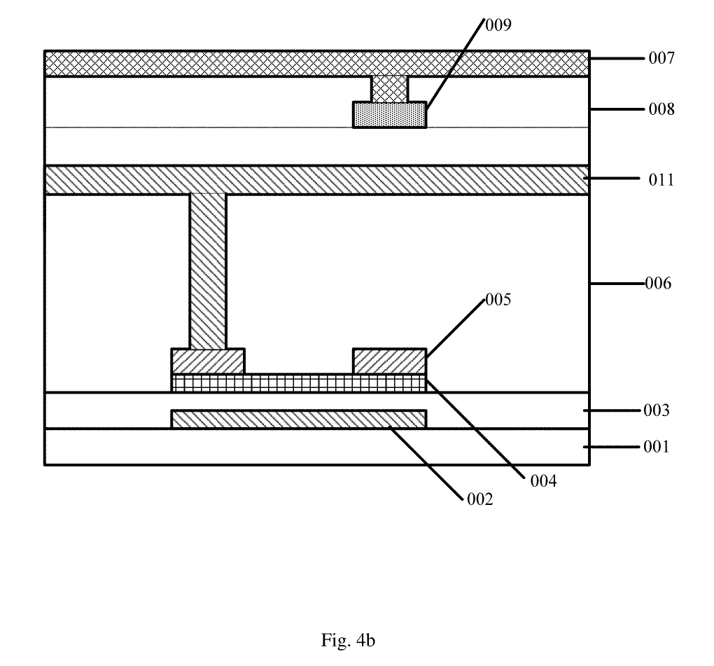

Based on an inventive concept of serving the common electrode as the touch detection electrodes, in the above display panel according to the exemplary embodiments of the present disclosure, as shown in FIG. 4a, the touch signal line 009 is provided in a film layer between the common electrode 007 and the pixel electrode 011, and electrically connected to the common electrode 007 by a via formed in a first insulation layer 008. The data line 005 and the touch control signal line 009 are provided in a resin layer 006 at a lower side of the common electrode 007 and the first insulation layer 008 at an upper side of the common electrode 007, respectively. A part of the film layer in a thickness direction of the display panel is provided between the touch control signal line 009 and the pixel electrode 011 of the sub pixels. In this way, there are the resin layer 006 having a thickness of about 15000 Å, and the first insulation layer 008 between the touch signal line 009 and the data line 005. Thereby, a capacitance between the touch signal line 009 and the data line 005 is small, in this way, the touch signal line 009 has little influence on the delay (loading) of the data line 005. On the other hand, there is only the first insulation layer 008, a thickness of which is about 2500 Å, between the touch signal line 009 and the common electrode 007, and the touch signal line 009 has some influence on other touch detection electrodes which are overlapped and unconnected.

Furthermore, in the above display panel according to embodiments of the present disclosure, the relative position between the common electrode 007 and the pixel electrode 011 of the sub pixels may be set as shown in FIG. 4a, that is, the pixel electrode 011 is located above the common electrode 007 in the thickness direction of the display panel. In this case, the common electrode 007 may shield an electric field generated by the data line, and it may prevent the electric field generated by the data line from interfering with the pixel electrode 011, and crosstalk is not easily occurred. In another embodiment, the relative position between the common electrode 007 and the pixel electrode 011 of the sub pixels also may be set as shown in FIG. 4b, that is, the pixel electrode 011 is located below the common electrode 007 in the thickness direction of the display panel. Compared with the embodiment where the pixel electrode 011 is located above the common electrode 007 as shown in FIG. 4a, the pixel structure in the embodiment shown in FIG. 4b may reduce one masking process during making the pixel structure.

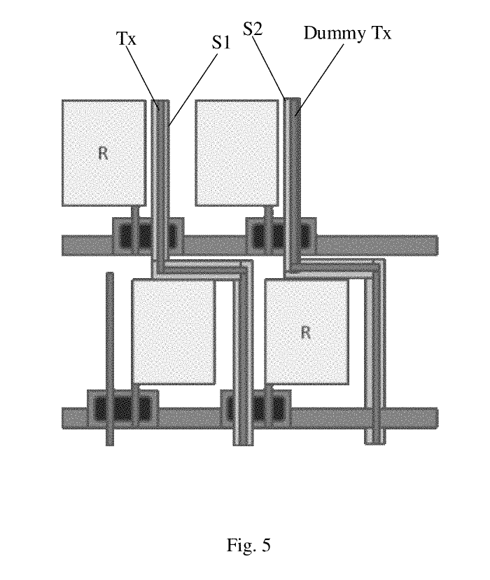

In the display device with barrow bezel, in order to avoid the touch signal lines from being led out from left and right ends of the display panel, in the above display panel according to embodiments of the present disclosure, as shown in FIG. 5, extending directions of the touch signal lines Tx are generally designed to be consistent with that of the data lines S, respectively, that is, the touch signal lines Tx is set to extend in the column direction in the column gap between the sub pixels.

Furthermore, in order not to affect the aperture ratio of the display panel, in the above display panel of an embodiment of the present disclosure, as shown in FIG. 5, an orthographic projection of the data line S, which is located in the column gap between two columns of sub pixels, on a plane perpendicular to the thickness direction of the display panel generally covers an orthographic projection of the touch signal line Tx in the same column gap, that is, the line width of the touch signal line Tx is generally not larger than that of the data line S. For example, the line width of the touch signal line Tx is set to overlap with the line width of the data line S.

Furthermore, in the above display panel of an embodiment of the present disclosure, because the accuracy of touch operation is far less than the display accuracy, the number of touch detection electrodes is much less than the number of the sub pixels. When the touch signal lines correspond to the touch detection electrodes one by one, there will be a sub pixel gap without the touch signal line. In order to ensure the whole wiring of the display panel is even, and the display effect is uniform, as shown in FIG. 5, floating touch signal lines Dummy Tx, extending directions of which are consistent with those of the data lines, respectively, may be provided in the column gap between two columns of sub pixels except for the column gap in which the touch signal lines Tx are provided.

Also, in order not to affect the aperture ratio of the display panel, in the above display panel of an embodiment of the present disclosure, as shown in FIG. 5, the orthographic projection of the data line S, which is in the column gap between two columns of sub pixels, on a plane perpendicular to the thickness direction of the display panel covers an orthographic projection of the floating touch signal lines Dummy Tx in the same column gap, that is, the line width of the floating touch signal lines Dummy Tx is generally not larger than that of the data line S. For example, the line width of the floating touch signal lines Dummy Tx is set to overlap with the line width of the data line S.

Furthermore, in order to facilitate the design of pixel structure, in the above display panel of an embodiment of the present disclosure, the sub pixels in alternate rows of sub pixels are arrange to be generally aligned to each other in the column direction, respectively. That is, odd rows of sub pixels are aligned to each other, and even rows of sub pixels are aligned to each other, respectively. For example, in three adjacent rows of sub pixels referred as a first row of sub pixels, a second row of sub pixels and a third row of sub pixels which are arranged sequentially, the first row of sub pixels and the third row of sub pixels are aligned to each other in the column direction, respectively.

In the above display panel of an embodiment of the present disclosure, the data line and the respective sub pixels may be connected in a manner of column-inversion, that is, each data line is connected to pixel switches of the sub pixels located at the same side of the data line. In this case, as shown in FIG. 6, each data line S1, S2, . . . , S6 is connected to at least two colors of sub pixels. When displaying a solid (single) color image, it needs to turn on multiple data lines that are connected to the sub pixels displaying the solid color image. For example, when it needs to display a red image, it needs to turn on four data lines S1, S2, S4 and S5.

In the above display panel according to another embodiment of the present disclosure, the data line and the respective sub pixels may be connected in a manner of Z-inversion. As shown in FIG. 1, each of the data lines S1, S2, . . . , S6 is only connected to pixel switches of the sub pixels which are located at different sides of the data line and have the same color. In this case, when displaying a solid color image, it needs to turn on the data lines that are connected to the sub pixels displaying the solid color image. For example, when it needs to display a red image, it needs to turn on two data lines S1 and S4. Thereby, the power consumption may be reduced.

Based on the same disclosure concept, according to an embodiment of another aspect of the present disclosure, there is provided a method of manufacturing the above display panel. As shown in FIG. 4a, if the common electrode is located below the pixel electrode, the method comprises a step of:

sequentially forming patterns of a gate electrode 002, a gate insulation layer 003, an active layer 004, data lines 005, a resin layer 006, a common electrode 007, a first insulation layer 008, a touch signal line 009, a second insulation layer 010 and a pixel electrode 011 on a substrate 001. In this method, the manufacture of the display panel may be finished by 10 patterning processes.

According to another embodiment of another aspect of the present disclosure, there is provided a method of manufacturing the above display panel. As shown in FIG. 4b, if the common electrode is located above the pixel electrode, the method comprises a step of:

sequentially forming patterns of a gate electrode 002, a gate insulation layer 003, an active layer 004, data lines 005, a resin layer 006, a pixel electrode 011, a touch signal line 009 insulated from the pixel electrode 011, a first insulation layer 008 and a common electrode 007 on a substrate 001. In this method, the manufacture of the display panel may be finished by 9 patterning processes.

According to an embodiment of another aspect of the present disclosure, there is provided a display device comprising the display panel according to the above embodiments of the present disclosure. The display device may comprise any product or component having a display function, such as a mobile phone, a panel computer, a TV, a display, a notebook computer, a digital photo frame, a navigator, etc. The implementation of the display device may refer to the embodiments of the above display panel, and further descriptions about the display device are omitted herein.

In the display panel, the method of manufacturing the display panel and the display device according to the exemplary embodiments of the present disclosure, in the display panel using rendering technology, the pixel structure is formed by sub pixels compactly arranged in rows and columns; the sub pixels in each row of sub pixels are arranged to be aligned with each other; the sub pixels in one row of sub pixels of two adjacent rows of sub pixels are offset from those in the other row of sub pixels, respectively, in the column direction by X (0<X<1) times of width of the sub pixel, and each sub pixels in each row of sub pixels have different colors from the adjacent sub pixel. Based on this, the touch detection electrodes are used as the common electrode of the sub pixels, the touch signal lines are provided in the film layer between the common electrode and the pixel electrode of the sub pixels. That is, by use of the gap between two rows of sub pixels, the data lines and the touch signal lines are provided in different film layers. The touch signal lines are provided in the film layer between the pixel electrode and the common electrode, and electrically connected to the common electrode, which also used as the touch detection electrode, by the vias formed in the insulation layer. By providing the touch signal line and the data line in different film layers, respectively, it will neither affect the aperture ratio of the display panel, nor lead to the luminous environment difference between the sub pixels caused by providing the touch signal lines. Moreover, since the data line and the touch signal line are located in different film layers, it may avoid the short circuit from being occurred between them.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

1. A display panel, comprising:
a plurality of sub pixels arranged in rows and columns, wherein sub pixels in a first row of two adjacent rows of sub pixels are offset from sub pixels in a second row of the two adjacent rows, respectively, in a column direction, and each sub pixel has a different color from an adjacent sub pixel;
a plurality of data lines extending in the column direction in a column gap between the sub pixels;
a plurality of touch signal lines provided in a gap between the sub pixels; and
a plurality of touch detection electrodes electrically connected to the plurality of touch signal lines, respectively,
wherein the touch detection electrodes are used as a common electrode of the sub pixels, and each of the touch signal lines is provided in a film layer between the common electrode and a pixel electrode of the sub pixels, respectively, and
wherein a part of the film layer in a thickness direction of the display panel is provided between the touch control signal lines and the pixel electrode of the sub pixels.

2. The display panel according to claim 1, wherein extending directions of the touch signal lines are consistent with those of the data lines, respectively.

3. The display panel according to claim 2,
wherein an orthographic projection of one of the data lines, which is in the column gap between two columns of sub pixels, on a plane perpendicular to the thickness direction of the display panel covers an orthographic projection of a respective touch signal line in the same column gap.

4. The display panel according to claim 2,
wherein the touch signal lines are in one-to-one correspondence to the touch detection electrodes, and
wherein a floating touch signal line is provided in the column gap between two columns of sub pixels except for a column gap in which one of the touch signal lines is provided, and an extending direction of the floating touch signal line is consistent with that of the data lines.

5. The display panel according to claim 4,
wherein an orthographic projection of one of the data lines, which is in the column gap between two columns of sub pixels, on a plane perpendicular to the thickness direction of the display panel covers an orthographic projection of the floating touch signal line in the same column gap.

6. The display panel according to claim 1,
wherein in a first row of sub pixels, a second row of sub pixels and a third row of sub pixels which are arranged sequentially, the first row of sub pixels and the third row of sub pixels are aligned to each other in the column direction, respectively.

7. The display panel according to claim 1,
wherein each of the data lines is only connected to pixel switches of the sub pixels located at different sides of the data line and having the same color.

8. The display panel according to claim 1,
wherein each of the data lines is connected to pixel switches of the sub pixels located at the same side of the data line.

9. A display device comprising a display panel, wherein the display panel comprises:
a plurality of sub pixels arranged in rows and columns, wherein sub pixels in a first row of two adjacent rows of sub pixels are offset from sub pixels in a second row of the two adjacent rows, respectively, in a column direction, and each sub pixel has a different color from an adjacent sub pixel;
a plurality of data lines extending in the column direction in a column gap between the sub pixels;
a plurality of touch signal lines provided in a gap between the sub pixels; and
a plurality of touch detection electrodes electrically connected to the plurality of touch signal lines, respectively,
wherein the touch detection electrodes are used as a common electrode of the sub pixels, and each of the touch signal lines is provided in a film layer between the common electrode and a pixel electrode of the sub pixels, respectively, and
wherein a part of the film layer in a thickness direction of the display panel is provided between the touch control signal lines and the pixel electrode of the sub pixels.

10. A method of manufacturing the display panel according to claim 1, comprising a step of:
sequentially forming patterns of a gate electrode, a gate insulation layer, an active layer, source and drain data lines, a resin layer, the common electrode, a first insulation layer, the touch signal lines, a second insulation layer and the pixel electrodes on a substrate; or
sequentially forming patterns of a gate electrode, a gate insulation layer, an active layer, source and drain data lines, a resin layer, the pixel electrodes, the touch signal lines insulated from the pixel electrodes, a first insulation layer and the common electrode layer on a substrate.

11. The display panel according to claim 1, wherein the data lines are provided in an additional film layer different from the film layer between the common electrode and the pixel electrode of the sub pixels, respectively.

12. The display device according to claim 9, wherein the data lines are provided in an additional film layer different from the film layer between the common electrode and the pixel electrode of the sub pixels, respectively.

13. The display device according to claim 9, wherein extending directions of the touch control signal lines are consistent with those of the data lines, respectively.

14. The display device according to claim 13,
wherein an orthographic projection of one of the data lines, which is in the column gap between two columns of sub pixels, on a plane perpendicular to the thickness direction of the display panel covers an orthographic projection of a respective touch signal line in the same column gap.

15. The display device according to claim 13,
wherein the touch signal lines are in one-to-one correspondence to the touch detection electrodes, and
wherein a floating touch signal line is provided in the column gap between two columns of sub pixels except for a column gap in which one of the touch signal lines is provided, and an extending direction of the floating touch signal line is consistent with that of the data lines.

16. The display device according to claim 15,
wherein an orthographic projection of one of the data lines, which is in the column gap between two columns of sub pixels, on a plane perpendicular to the thickness direction of the display panel covers an orthographic projection of the floating touch signal line in the same column gap.

17. The display device according to claim 9,
wherein in a first row of sub pixels, a second row of sub pixels and a third row of sub pixels which are arranged sequentially, the first row of sub pixels and the third row of sub pixels are aligned to each other in the column direction, respectively.

18. The display device according to claim 9,
wherein each of the data lines is only connected to pixel switches of the sub pixels located at different sides of the data line and having the same color.

19. The display device according to claim 9,
wherein each of the data lines is connected to pixel switches of the sub pixels located at the same side of the data line.
